(19) United States
(12) Patent Application Publication
(10) Pub. No.: US 2007/0101035 A1
(43) Pub. Date: May 3, 2007

(54) Pc card and pc card control method

(75) Inventors: Masayoshi Son, Tokyo (JP); Satoru Yoshikawa, Aichi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: SOFTBANK BB CORP., Tokyo (JP); SUNCORPORATION, Aichi (JP)

(21) Appl. No.: 10/554,398

(22) PCT Filed: Apr. 21, 2004
(86) PCT No.: PCT/JP04/05734

§ 371 Date: Nov. 15, 2006

(30) Foreign Application Priority Data
Apr. 24, 2003 (JP) 2003-120202

(51) Int. Cl. H05K 7/10; G06F 13/00

(52) U.S. Cl. 710/301

(57) ABSTRACT

A PC card and a method of controlling the PC card are provided which can be used to add multiple capabilities to an information processing apparatus in cooperation with a conventional card only by the use of a single card slot.

The PC card 1 is provided with a multifunctional adapter unit 2 which controls data exchange between the information processing apparatus 20 and the function of the PC card or data exchange between the information processing apparatus 20 and the function of the PHS card, and a PC card function control unit 3 which controls the function of the PC card. The multifunctional adapter unit 2 is provided with a communication control unit 2a, an area builder unit 2b, an address control unit 2c, an interrupt request control unit 2d, and an interrupt cause register set 2e. A global card information structure and a global register area are built in the multifunctional adapter unit 2 by the area builder unit 2b in order to control the address operations to the PC card 1 by the information processing apparatus when the information processing apparatus refers to the PC card, and thereby both the memory spaces of the PC card function control unit 3 and the PHS card function control unit 4 can be accessed.

### TECHNICAL FIELD

The present invention relates to a PC card and a method of controlling the PC card which can be used to add multiple capabilities to an information processing apparatus.

### BACKGROUND ART

A PC card provides a wireless LAN capability, a PHS communication capability, a portable telephone communication capability, a memory capability and so forth, and can be plugged into an information processing apparatus such as a personal computer to make use of these capabilities. In order to add multiple capabilities to an information processing apparatus, a plurality of PC cards have to be plugged into the information processing apparatus, and therefore a plurality of slots must be available for connection. As conventional personal computers have been downsized, in many models, particularly laptop personal computers, there is only one slot for a PC card to enable a functional extension.

On the other hand, the technique is disclosed that a plurality of PC cards are linked in series so that multiple capabilities can be added to a personal computer only by the use of a single slot (for example, refer to Japanese Patent Published Application No. Hei 2000-75974, paragraph “0027”, FIG. 3).

However, in the case where a plurality of PC cards are simply connected to each other, they can be easily come off from each other and therefore it is not practical. In addition, Such a PC card has a special structure for the serial connection and a proprietary controller inside thereof and therefore conventional cards cannot be used.

Taking into consideration the above shortcomings, it is an object of the present invention to provide a PC card which can be used to add multiple capabilities to an information processing apparatus in cooperation with a conventional card only by the use of a single card slot, and a method of controlling this PC card.

### SUMMARY OF THE INVENTION

In order to accomplish the above object, the first feature of the present invention resides in a PC card having a connection plug connectable to an information processing apparatus, and a card connector through which an additional card can be connected, wherein multiple capabilities are added to the information processing apparatus by connecting the PC card to the information processing apparatus comprising:

(a) a communication control unit configured to control communication between the information processing apparatus and a function control unit of the PC card, and communication between the information processing apparatus and a function control unit of the additional card; and

(b) an area builder unit configured to analyze a card information structure of the additional card, build a global card information structure from the card information structure of the additional card together with a card information structure of tho PC card, analyze card configuration information of the additional card, and build a global register area from the card configuration information of the additional card together with a card configuration information of the PC card.

In this description, a “PC card” is a card which is inserted into an information processing apparatus to add a certain capability such as a wireless capability or a memory capability to the information processing apparatus. Such an information processing apparatus may be a personal computer (PC), a notebook type personal computer, or any other appropriate device such as a cellular phone, a PHS, a PDA, an electronic organizer, a digital camera, a car navigation system, a scanner, or a printer. Also, the “card information structure” is information about the type of card, the manufacturer, the name of product, and other properties of an individual card as determined in advance. The “card configuration information” is information required for activating the card including setting registers such as CCOR (Card Configuration Option Register) and CCSR (Card Configuration Status Register), the base addresses of the setting registers, the drive voltage level, the type of interface, the capability of the device, the IRQ number and so forth.

By the use of the PC card in accordance with the first feature of the present invention, it is possible to add multiple capabilities to an information processing apparatus in cooperation with a conventional card only by the use of a single card slot. Also, it is possible to control address operations in order to access both the address area used by the function control unit of the PC card and the address area used by the function control unit of the additional card in the memory space, which is accessed by the information processing apparatus through the PC card, by building the global card information structure and the global register.

In addition, the PC card in accordance with the first feature further comprises an address control unit configured to switch address operations in order that a functional register group of the PC card is located in an I/O area of the PC card when the information processing apparatus outputs an I/O area control signal for accessing the function of the PC card, and that a functional register group of the additional card is located in the I/O area of the PC card when the information processing apparatus outputs an I/O area control signal for accessing the function of the additional card. In accordance with this PC card, the information processing apparatus can access both the I/O areas of the function control unit of the PC card and the function control unit of the additional card.

In addition, the PC card in accordance with the first feature further comprises an interrupt request control unit that, when an interrupt request is received from the function control unit of the PC card or the function control unit of the additional card, sets information about the interrupt request in an interrupt cause register. In accordance with this PC card, even if only one interrupt request signal is available for the card slot, the information processing apparatus can recognize both the interrupt requests of the PC card and the additional card inserted thereinto.

Furthermore, in the PC card in accordance with the first feature, the function control unit of the PC card is provided with a wireless LAN communication capability, and the function control unit of the additional card is provided with a PHS communication capability. In accordance with this PC card, it is possible to add a wireless communication capability and a PHS communication capability to the information processing

A second feature of the present invention resides in a method of controlling a PC card having a connection plug connectable to an information processing apparatus, and a card connector through which an additional card can be connected, wherein multiple capabilities are added to the information processing apparatus by connecting the PC card to the information processing apparatus, the method comprising:

(a) a step of controlling communication between the information processing apparatus and a function control unit of the PC card, and communication between the information processing apparatus and a function control unit of the additional card; and

(b) a step of analyzing a card information structure of the additional card, building a global card information from the card information structure of the additional card together with a card information structure of the PC card, analyzing card configuration information of the additional card, and building a global register area from the card configuration information of the additional card together with a card configuration information of the PC card.

The method of controlling a PC card in accordance with the second feature of the present invention makes it possible to add multiple capabilities to the information processing apparatus in cooperation with a conventional card only by the use of a single card slot. Also, it is possible to control address operations in order to access both the address area used by the function control unit of the PC card and the address area used by the function control unit of the additional card in the memory space, which is accessed by the information processing apparatus through the PC card, by building the global card information structure and the global register.

Also, the method of controlling a PC card in accordance with the second feature may further comprises a step of switching address operations in order that a functional register group of the PC card is located in an I/O area of the PC card when the information processing apparatus outputs an I/O area control signal for accessing the function of the PC card, and that a functional register group of the additional card is located in the I/O area of the PC card when the information processing apparatus outputs an I/O area control signal for accessing the function of the additional card.

In accordance with this method of controlling a PC card, the information processing apparatus can access both the I/O areas of the function control unit of the PC card and the function control unit or the additional card.

Furthermore, the method of controlling a PC card in accordance with the second feature may further comprises a step of, when an interrupt request is received from the function control unit of the PC card or the function control unit of the additional card, setting information about the interrupt request in an interrupt cause register. In accordance with this method of controlling a PC card, even it only one interrupt request signal is available for the card slot, the information processing apparatus can recognize both the interrupt requests of the PC card and the additional card inserted thereinto.

### BRIEF DESCRIPTION OF THE DRAWINGS

FIG. 1 is a perspective view showing a PC card in accordance with an embodiment of the present invention.

FIG. 2 is a view showing the PC card in accordance with the embodiment of the present invention into which a PHS card is inserted.

FIG. 3 is a block diagram showing the configuration of the PC card in accordance with the embodiment of the present invention.

FIG. 4 is a view for explaining the address control by a multifunctional adapter unit.

FIG. 5 is a flowchart showing the initialization process of the control method of the PC card in accordance with the embodiment of the present invention.

FIG. 6 is a flowchart showing an interrupt handling process of the control method of the PC card in accordance with the embodiment of the present invention.

### BEST MODE FOR CARRYING OUT THE INVENTION

Next, with reference to drawings, an embodiment in accordance with the present invention will be explained. Throughout the following drawings, like references indicate functionally same or similar elements. However, the drawings are presented only schematically, and the actual thicknesses and dimensions should be determined taking into consideration the following description.

(Outer Configuration of a PC Card)

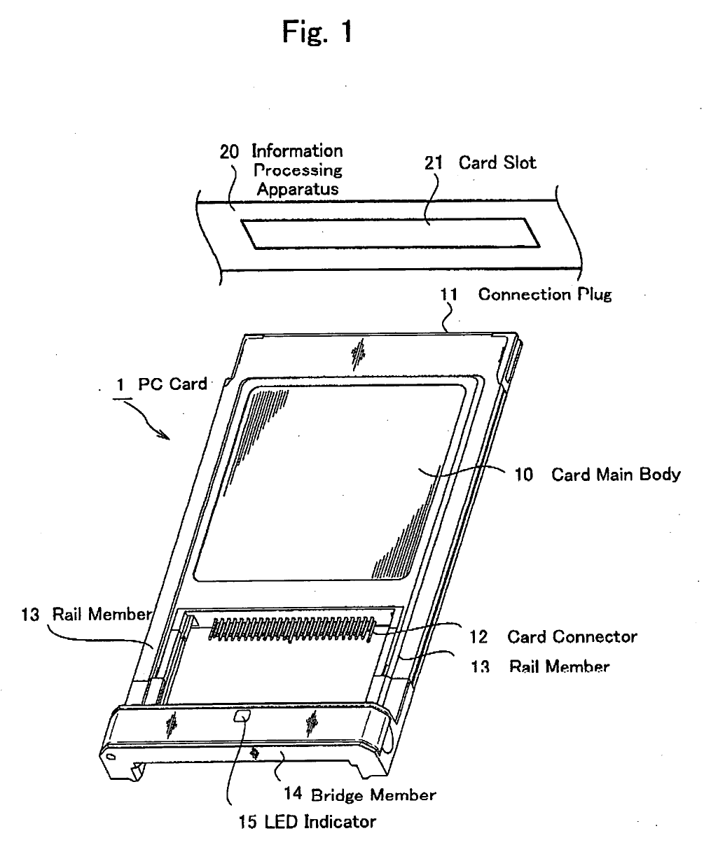

The PC card in accordance with the first embodiment of the present invention comprises a card main body 10 to be inserted into a card slot 21 of an information processing apparatus 20, a pair of parallel rail members 13, and a bridge member 14 with which the pair of the rail members 13 are connected as illustrated in FIG. 1.

The card main body 10 is provided with a connection plug 11 for connecting with the information processing apparatus 20, and a card connector 12 to which an additional card can be connected. The card main body 10 is provided with a capability implemented therein such as a wireless LAN capability, a PHS communication capability, a portable telephone communication capability, a memory capability or the like, and serves to add multiple capabilities including the capability of the additional card to the information processing apparatus 20.

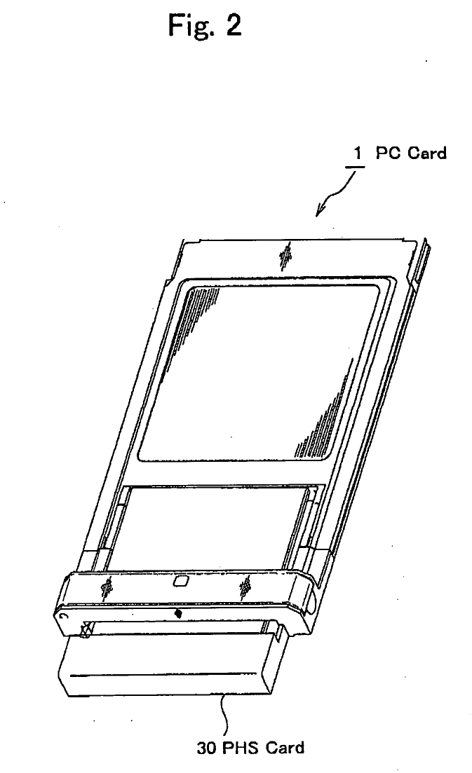

The rail members 13 is used to guide the additional card for insertion. FIG. 2 shows the PC card 1 into which a PHS card 30 is inserted as an additional card. The PHS card 30 is inserted into the PC card 1 along the rail members 13, and connected to the card connector 12.

The bridge member 14 is located in order not to block the insertion path of the additional card 30 when the PHS card 30 is inserted between the rail members 13. Since the bridge member 19 is provided, it is possible to improve the stiffness of the rail members 13 and the ability of holding the PHS card 30 as inserted. Incidentally, in the case where the PC card has a communication capability, the bridge member 14 is preferably provided with an LED indicator 15. The LED indicator 15 serves to indicate the communication state, for example, by illuminating blue during communication, so that the user can visually confirm the current communication state.

The additional card as inserted into the PC card is preferably a CF Type I or CF Type II card designed in compliance with the CFA (Compact Flash Association) standard. More specifically speaking, a Compact Flash (registered trademark) card (CF card) can be used besides a PHS card. The standard size of CF Type I is 36.4 mm length×42.8 mm width×3.3 mm thickness, and the standard size of CF Type II is 36.4 mm length×42.8 mm width×5.0 mm thickness. The PC card 1 in accordance with the embodiment is provided with the card connector 12 in conformity with this type of the card 30, and the rail members 13 and the bridge member 14 can be designed to hold any card which is compliant with this standard. If the PC card 1 in accordance with the embodiment is designed to have, the above outer dimensions, there is the advantage that a marketed card can be used as the additional card 30.

On the other hand, the outer dimensions of the PC card 1 in accordance with the embodiment are preferably in compliance with the PC card standard Type I, Type II and Type III.

Since a conventional card can be inserted into the PC card 1 in accordance with the first embodiment, both the function of the PC card 1 and the function of the conventional card 30 as inserted thereinto can be added to the information processing apparatus 20 by the use of only one card slot 21 of the information processing apparatus 20. Also, by providing the bridge member 14, it is possible to secure the stiffness of the frame member 13 longitudinally extended in order that the additional card 30 is inserted into it, and also possible to enhance the facility of holding the additional card ward 30.

(Internal Functions of the PC Card)

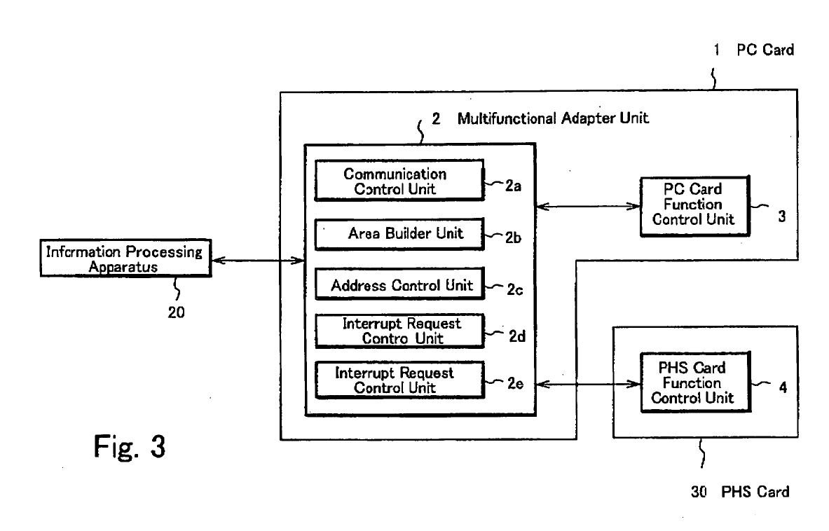

Next, the internal function of the PC card 1 in accordance with the embodiment of the present invention will be explained with reference to FIG. 3. In the following explanation, it is assumed that the additional card inserted into the PC card 1 is a PHS card which is compliant with the CFA standard.

The PC card 1 is provided with a multifunctional adapter unit 2 which controls data exchange between the information processing apparatus 20 and the function of the PC card or data exchange between the information processing apparatus 20 and the function of the PHS card, and a PC card function control unit 3 which controls the function of the PC card.

The function of the PC card is controlled by the PC card function control unit 3, and can be one of a wireless LAN capability, a PHS communication capability, a portable telephone communication capability, a memory capability and so forth. The PC card function control unit 3 and the multifunctional adapter unit 2 can be implemented within a single IC chip.

The PHS card 30 has a PHS communication capability which is controlled by a PHS card function control unit 4. In the case of the embodiment of the present invention, since the additional card inserted into the PC card is a PHS card, a PHS communication capability is added. However, needless to say, the additional card can be a card having a wireless LAN communication capability, a memory capability or the like. For example, if the PC card 1 incorporates a wireless LAN the communication capability with a PHS card inserted thereinto, both the wireless LAN communication capability and the PHS communication capability can be added to the information 30 processing apparatus 20. In this case, if a wireless LAN service can be used, the information processing apparatus 20 starts communication through the wireless LAN, and if no wireless LAN service can be used, the information processing apparatus 20 can start communication by the PHS communication capability.

The multifunctional adapter unit 2 of the PC card 1 in accordance with the embodiment of the present invention is provided with a communication control unit 2a, an area builder unit 2b, an address control unit 2c, a driving system setting unit 2c, an interrupt request control unit 20, and an interrupt cause register set 2e.

The communication control unit 2a controls the communication between the information processing apparatus 20 and the PC card function control unit 3, and the communication between the information processing apparatus 20 and the PHS card function control unit 4.

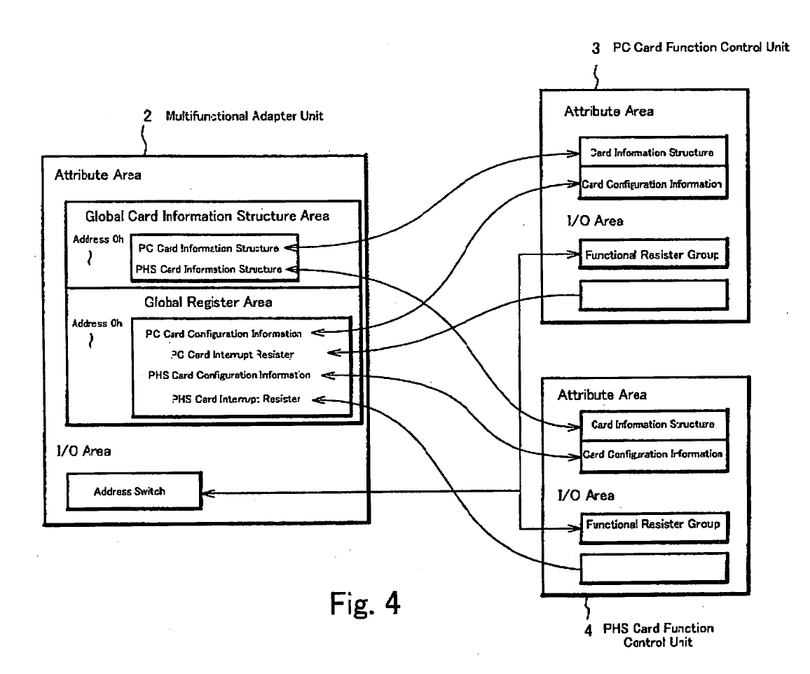

The area builder unit 2b controls address operations in order that an global card information structure area and a global register area are built in the memory space which is accessed by the information processing apparatus 20 through the PC card 1 to refer to both the memory spaces of the PC card function control unit 3 and the PHS card function control unit 4. The details of the area building operation and the method of controlling addresses will be explained with reference to FIG. 4.

The memory space for each of the PC card function control unit 3 and the PHS card function control unit 4 includes an attribute area in which card information is stored, and an I/O area in which a register group is allocated for use in the operation of the function of the PC card such as a communication capability. The attribute area is used to store card property information (a Card Information Structure (CIS)) and card configuration information. The “card information structure” is information about the type of card, the manufacturer, the name of product, and other properties of an individual card as determined in advance. The “card configuration information” is information required for activating the card including setting registers such as CCOR (Card Configuration Option Register) and CCSR (Card Configuration Status Register), the base addresses of the setting registers, the drive voltage level, the type of interface, the capability of the device, the IRQ number and so forth.

A PC card driver is installed in the information processing apparatus 20 which can recognize and access the locations of the attribute area and I/O area through the driver. However, since there are the attribute areas and the I/O areas of both the PC card and the PHS card in the case of the embodiment or the present invention, the multifunctional adapter unit 2 is responsible for making it possible for the information processing apparatus 20 to recognize these areas for both the PC card and the PHS card.

For this purpose, the area builder unit 2b serves to analyze the card information structure of the PHS card function control unit 4, and build the global card information structure area together with the card information structure of the PC card function control unit 3 in the multifunctional adapter unit 2. The global card information structure is a card information structure which is in compliance with the standard of PC cards, and thereby the information processing apparatus 20 can access a plurality of card information structures without need to modify the internal system of the information processing apparatus 20. In a like manner, the area builder unit 2b serves to analyze the card configuration information of the PHS card function control unit 4, and build global registers also with reference to the card configuration information of the PC card function control unit 3 in the multifunctional adapter unit 2. Since the global registers are also registers which are in compliance with the standard of PC cards, the information processing apparatus 20 can access the respective registers having a plurality of functions without need to modify the internal system of the information processing apparatus 20. As has been discussed above, the PC card in accordance with the embodiment of the present invention is provided with a configuration mechanism (Function Configuration Register (FCR)) which is compliant with the PC card standard in Order to realize a multifunctional facility. Even if the additional card inserted into the PC card in accordance with the embodiment of the present invention is a marketed card (PHS card in this case) which is not designed to support a multifunctional facility, the PC card in accordance with the embodiment of the present invention is united with the additional card inserted thereinto to function as a multifunctional card.

In addition, the area builder unit 2b locates the card information structure of the PC card function control unit 3 and the card information structure of the PHS card function control unit 4 from address 0h of the global card information structure area as illustrated in FIG. 4. Also, the area builder unit 2b locates the card configuration information of the PC card function control unit 3 and the card configuration information of the PHS card function control unit 4 from address 0h of a global register area. Furthermore, the area builder unit 2b builds a PC card interrupt resister for saving interrupt request information as transmitted from the PC card function control unit 3 and a PHS card interrupt resister for saving interrupt request information as transmitted from the PHS card function control unit 4 also in the global register area. The PC card interrupt resister saves the information by, for example, setting a flag when an interrupt request signal from the PC card function control unit 3. This is true also for the PHS card interrupt resister.

The address control unit 2c serves to switch the I/O area in response to an I/O area control signal as output from the information processing apparatus 20. Namely, when an I/O area control signal indicative of accessing the function of the PC card is output from the information processing apparatus 20, addresses are located by the address control unit 2c in order to access the functional register group of the PC card function control unit 3. On the other hand, when an I/O area control signal indicative of accessing the function of the PHS card is output from the information processing apparatus 20, addresses are located by the address control unit 2c in the I/O area in order to access the functional register group of the PHS card function control unit 4.

When receiving an interrupt request from the PC card function control unit 3, the interrupt request control unit 2d sets the interrupt cause register set 2e to indicate the cause of the interrupt. More specifically speaking, the interrupt information is saved by, for example, setting the PC card interrupt resister of the interrupt cause register set 2e. On the other hand, when receiving an interrupt request from the PHS card function control unit 4, the interrupt request control unit 2d sets the interrupt cause register set 2e to indicate the cause of the interrupt in the same manner. More specifically speaking, the interrupt information is saved by, for example, setting the PHS card interrupt resister of the interrupt cause register set 2e.

The interrupt cause register set 2e comprises the PC card interrupt resister and the PHS card interrupt resister. The PC card interrupt resister saves the cause of the interrupt as received from the PC card function control unit 3. On the other hand, the PHS card interrupt resister saves the cause of the interrupt as received from the PHS card function control unit 4.

In accordance with the PC card 1 of the embodiment of the present invention, it is possible to add multiple capabilities to the information processing apparatus 20 with the conventional card 30 only by the use of one card slot 21. Also, the global card information structure area and the global register area are built in the multifunctional adapter unit 2 by the area builder unit 2b in order to control the address operations to the PC card 1 by the information processing apparatus 20, and thereby both the memory spaces of the PC card function control unit 3 and the PHS card function control unit 4 can be accessed.

Also, both the I/O areas of the PC card function control units of the PC card and the additional card can be accessed through the address control unit 2c. Furthermore, the interrupt request control unit 2d can control the process of handling both the interrupts issued from the functions of the PC card 1 and the PHS card 30 by setting tho cause of the interrupt as issued from the PC card function control unit 3 and the PHS card function control unit 4 in the interrupt cause register set 2e.

(Control Method of the PC Card)

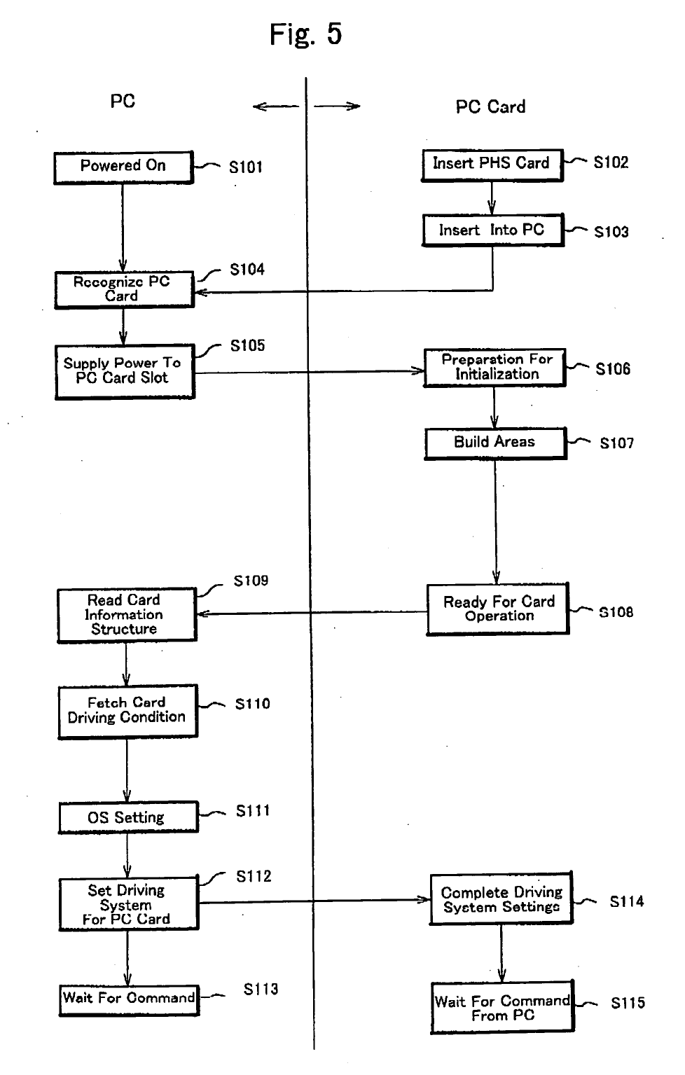

Next, the method of controlling the PC card in accordance with the present invention will be explained. First of all, the initialization of the PC card will be explained with reference to FIG. 5 together with FIG. 1 and FIG. 3. Incidentally, in the following explanation, it is assumed that the card inserted into the PC card is a PHS card, and that the information processing apparatus into which the PC card is inserted is a personal computer (referred to herein as “PC”).

(a) First, the PC 20 is powered up in step S101 of FIG. 5. On the other hand, in step S102, the PHS card 30 is inserted into the PC card 1 which in turn is inserted into the PC 20. Next, the PC 20 recognizes insertion of the PC card 1 in step S104, and then supplies power to the PC card slot 21 in step S105.

(b) Next, in step S106, the necessary preparations are performed for initializing the inside circuit of the PC card. 1o In this case, the communication control unit 2a of the multifunctional adapter unit 2 recognizes the memory space of the PC card function control unit 3 and the memory space of the PHS card function control unit 4. Next, the global card information structure area and the global register area are built in the multifunctional adapter unit 2 in step S107 by the area builder unit 2b in order to control the address operations to the PC card 1 by the information processing apparatus 20, and thereby both the memory spaces of the PC card function control unit 3 and the PHS card function control unit 4 can be accessed. Namely, the area builder unit 2b serves to analyze the card information structure of the PHS card function control unit 4, and build the global card information structure area together with the card information structure of the PC card function control unit 3 in the multifunctional adapter unit 2.

Then, the card information structures are located from address 0h of the global card information structure area. In a like manner, the area builder unit 2b serves to analyze the card configuration information of the PHS card function control unit 4, and build the global register area together with the card configuration information of the PC card function control unit 3 in the multifunctional adapter unit 2. Then, the card information structures are located from address 0h of the global register area. At this time, the area builder unit 2b also builds the PC card interrupt resister and the PHS card interrupt resister in the global register area. The details of the interrupt resisters will be explained the following description of the interrupt handlers.

Incidentally, the I/O areas of the PC card function control unit 3 and the PHS card function control unit 4 are switchingly accessed by the address control operation of the address control unit 2c in accordance with the I/O area control signal as transmitted from the PC. Namely, when an I/O area control signal indicative of accessing the function of the PC card is output from the PC 20, addresses are located by the address control unit 2c in the I/O area in order to access the functional register group of the PC card function control unit 3. On the other hand, when an I/O area control signal indicative of accessing the function of the PHS card is output from the PC 20, addresses are located by the address control unit 2c in the I/O area in order to access the functional register group of the PHS card function control unit 4.

(d) After completing the preparation of driving these cards in step S108, the communication control unit 2a transmits a notification signal indicative of the completion of initialization to the PC 20. Next, in step S109, the PC 20 accesses the global card information structure of the multifunctional adapter unit 2 and reads the card information structure of the PC card and the PHS card.

(e) Next, in step Silo, the PC 20 fetches a card driving condition which has been registered in an INF file from a hard disk on the basis of the card information structures of the PC card and the PHS card as read. In the case of the configuration as illustrated in FIG. 4, for example, the INF file contains address information about the locations of the PC card configuration information, the PC card interrupt resister, the PHS card configuration information and the PHS card interrupt resister, and thereby the PC 20 can access the card configuration information of both the PC card and the PHS card. Also, both the PC card interrupt resister and the PHS card interrupt resister can be accesses.

(f) Next, in step S111, the PC 20 determines that the PC card 1 is a PC card having two capabilities corresponding to the function of the PC card and the function of the PHS card with reference to the card configuration information of the PC card, the card configuration information of the PHS card and so forth. Then, necessary settings are made in the OS in order that the two capabilities can work properly on the OS.

(g) Next, in step S112, the PC 20 performs the settings of the driving systems of both the PC card function control unit 3 and the PHS card function control unit 4. More specifically speaking, the settings of the CCOR contained in the card configuration information are performed. By this process, the PC card function control unit 3 and the PHS cord function control unit 4 are ready for operation, and the PC 20 is waiting for a command from an application software and so forth in step S113. On the other hand, after completing the settings of the driving system of the PC card function control unit 3 and the PHS card function control unit 4 in step S114, the PC card 1 is also waiting for a command from the PC 20 in step S115.

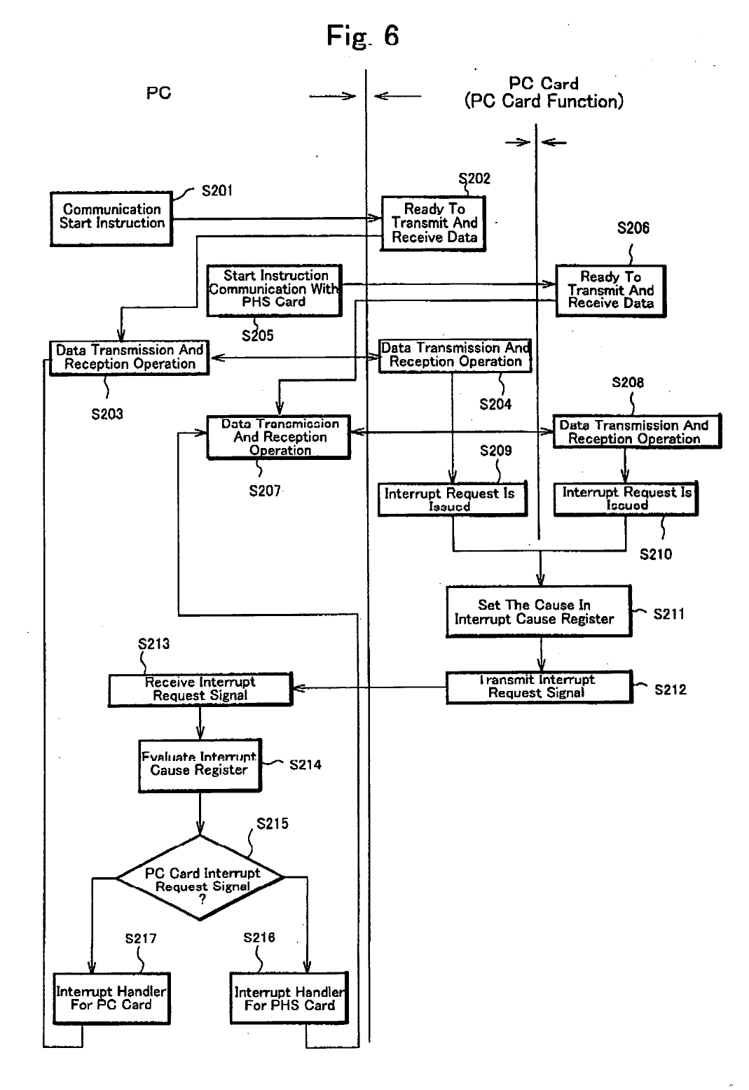

Next, the control method of the process of handling interrupts will be explained with reference to FIG. 6. Usually, since a PC card slot is assigned to only one interrupt request signal, when an interrupt request signal is received, the PC cannot identify which of the PC card function control unit 3 and the PHS card function control unit 4 issues the interrupt request signal. Because of this, when an interrupt request signal is received, the PC 20 accesses the PC card interrupt resister and the PHS card interrupt resister in order to determine which of them issues the interrupt request signal.

(a) First, in step S201, the PC 20 transmits a communication start instruction to the PC card. When the PC card function control unit 3 is ready to transmit and receive data in step S202, the data transmission and reception operation is performed between the PC 20 and the PHS card function control unit 3 through the communication control unit 2a of the multifunctional adapter unit 2 in steps S203 and S204. On the other hand, in step S205, the PC 20 transmits a communication start instruction to the PHS card. When the PHS card function control unit 4 is ready to transmit and receive data in step S206, the data transmission and reception operation is performed between the PC 20 and the PHS card function control unit 4 through the communication control unit 2a of the multifunctional adapter unit 2 in steps S207 and S208.

(b) In this case, it is assumed that an interrupt request is issued from the PC card function control unit 3 in step S209. This interrupt request is transmitted to the communication control unit 2a of the multifunctional adapter unit 2 from the PC card function control unit 3, and the interrupt request control unit 2d sets the cause of the interrupt by, for example, setting a flag in the PC card interrupt resister of the interrupt cause register set 2e of the global register area in step S211. The interrupt request is, for example, the interrupt request indicative that there is an available space occuring in a transmission buffer, the interrupt request indicative that there is incoming data, and so forth. On the other hand, in step S210, it is assumed that the PHS card function control unit 4 issues an interrupt request. This interrupt request is transmitted to the communication control unit 2a of the multifunctional adapter unit 2 from the PHS card function control unit 4, and the interrupt request control unit 2d sets the cause of the interrupt by, for example, setting a flag in the PHS card interrupt resister of the interrupt cause register 2e of the global register area in step S211.

(c) A flag (the cause of the interrupt) is set in the interrupt cause register set 2e, the communication control unit 2a of the multifunctional adapter unit 2 transmits an interrupt request signal to the PC 20 in step S212. After receiving the interrupt request signal in step S213, the PC 20 accesses the interrupt cause register set 2e in step S214.

(d) If the flag is set in the PC card interrupt resister in step S215, the PC 20 determines that the interrupt request signal is issued by the PC card function control unit 3, and proceeds to step S216 in which the interrupt handler of the function of the PC card is invoked. On the other hand, if the flag is set in the PHS card interrupt resister, the PC 20 determines that the interrupt request signal is issued by the PHS card function control unit 4, and proceeds to step S217 in which the interrupt handler of the function of the PC card is invoked. If both the flags of the PC card interrupt resister and the PHS card interrupt resister are set in step S215, the PC 20 invokes both the interrupt handlers of the PC card and the PHS card.

In accordance with the control method of the PC card 1 in accordance with the embodiment of the present invention, it is possible to add multiple capabilities to the information processing apparatus with the conventional card 30 only by the use of one card slot 21. Also, the global card information structure and the global register area are built in the multifunctional adapter unit 2 by the area builder unit 2b in order to control the address operations to the PC card 1 by the information processing apparatus 20, and thereby both the memory spaces of the PC card function control unit 3 and the PHS card function control unit 4 can be accessed.

Also, both the I/O areas of the function control unit of the PC card and the function control unit of the additional card can be accessed through the address control unit 2c. Furthermore, the interrupt request control unit 2d can control the process of handling both the interrupts issued from the functions of the PC card 1 and the PHS card 30 by setting the cause of the interrupt as issued from the PC card function control unit 3 or the PHS card function control unit 4 in the interrupt cause register set 2e.

### Other Embodiments

While the present invention has been described in conjunction with the above embodiments, the present invention should not be limited to the description and drawings as part of the disclosure. The various alternative embodiments, practical applications and implementations will be apparent to those skilled in the art from the disclosure.

For example, while the additional card 30 as an example for explanation is in compliance with the CF Type standard in the case of the embodiments of the present invention, the PC card 1 in accordance with the present invention can be used with a card, even if it is in compliance with another standard and cannot be attached directly to the PC card 1, as long as an appropriate adaptor is available through which the card can be connected to the card connector 12.

Also, the communication control unit 2a, the area builder unit 2b, the address control unit 2c, the interrupt request control unit 2a or the multifunctional adapter unit 2 in the internal structure of the PC card as described above can be implemented by hardwired control such as circuitry, or can be implemented by running a dedicated program which is written in a predetermined program.

Needless to say, like this example, a variety of embodiments of the present invention are possible even if not described here. Accordingly, the present invention should be limited only by matters defining an invention in the claims which are appropriate from the view point of the description.

### INDUSTRIAL APPLICABILITY

In accordance with the present invention, it is possible to provide a PC card and a method of controlling the PC card which can be used to add multiple capabilities to an information processing apparatus in cooperation with a conventional card only by the use of a single card slot.

What is claimed is:

1. A PC card having a connection plug connectable to an information processing apparatus, and a card connector through which an additional card can be connected, wherein multiple capabilities are added to said information processing apparatus by connecting said PC card to said information processing apparatus, said PC card comprising:
a communication control unit configured to control communication between said information processing apparatus and a function control unit of said PC card, and communication between said information processing apparatus and a function control unit of raid additional card; and
an area builder unit configured to analyze a card information structure of said additional card, build a global card information structure from the card information structure of said additional card together with a card information structure of said PC card, analyze card configuration information of said additional card, and build a global register area from the card configuration information of said additional card together with a card configuration information of said PC card.

2. The PC card as claimed in claim 1 further comprising an address control unit configured to switch address operations in order that a functional register group of said PC card is located in an I/O area of said PC card when said information processing apparatus outputs an I/O area control signal for accessing the function of said PC card, and that a functional register group of said additional card is located in the I/O area of said PC card when said information processing apparatus outputs an I/O area control signal for accessing the function of said additional card.

3. The PC card as claimed in claim 1 further comprising an interrupt request control unit that, when an interrupt request is received from the function control unit of said PC card or the function control unit of said additional card, sets information about said interrupt request in an interrupt cause register.

4. The PC card as claimed in claim 1 wherein the function control unit of said PC card is provided with a wireless LAN communication capability, and
the function control unit of said additional card is provided with a PHS communication capability.

5. A method of controlling a PC card having a connection plug connectable to an information processing apparatus, and a card connector through which an additional card can be connected, wherein multiple capabilities are added to said information processing apparatus by connecting said PC card to said information processing apparatus, said method of controlling the PC card comprising:
a step of controlling communication between said information processing apparatus and a function control unit of said PC card, and communication between said information processing apparatus and a function control unit of said additional card; and
a step of analyzing a card information structure of said additional card, building a global card information from the card information structure of said additional card together with a card information structure of said PC card, analyzing card configuration information of said additional card, and building a global register area from the card configuration information of said additional card together with a card configuration information of said PC card.

6. The method of controlling a PC card as claimed in claim 5 further comprising a step of switching address operations in order that a functional register group of said PC card is located in an I/O area of said PC card when said information processing apparatus outputs an I/O area control signal for accessing the function of said PC card, and that a functional register group of said additional card is located in the I/O area of said PC card when said information processing apparatus outputs an I/O area control signal for accessing the function of said additional card.

7. The method of controlling a PC card as claimed in claim 5 further comprising a step of, when an interrupt request is received from the function control unit of said PC card or the function control unit of said additional card, setting information about said interrupt request in an interrupt cause register.
